(19) United States
(12) Patent Application Publication
(10) Pub. No.: US 2014/0266277 A1
(43) Pub. Date: Sep. 18, 2014

(54) SEMICONDUCTOR TESTING PROBE NEEDLE

(71) Applicant: Yun-Meng YEH, (US)

(72) Inventor: Yun-Meng YEH, (US)

(73) Assignee: CHENG YUN TECHNOLOGY CO., LTD., New Taipei City (TW)

(21) Appl. No.: 13/845,703

(22) Filed: Mar. 18, 2013

(51) Int. Cl. G01R 1/067; G01R 31/28

(52) U.S. Cl. CPC G01R 1/06722; G01R 31/2891
USPC 324/755.05

(57) ABSTRACT

A semiconductor testing probe needle for connecting to a circuit board for inspection and to an inspection main board of a testing apparatus includes a conductive shaft having two ends of a connection end and an inspection end for contacting with the circuit board for inspection. A spring column includes one end electrically connected to the connection end of the conductive shaft and another end abuts the inspection main board. A conductive wire is arranged along the spring column and includes one end electrically connected to the conductive shaft and another end provided to be electrically connected to the inspection main board.

### BACKGROUND OF THE INVENTION

1. Field of the Invention

The present invention relates to a testing probe needle, in particular, to a semiconductor testing probe needle used for circuit inspection.

2. Description of Related Art

Probe cards are commonly used as a means for circuit inspection in the semiconductor manufacturing process, which mostly consist of arrays of probe needles. The arrangement of the probe needles are configured corresponding to the circuit layout on the circuit board to be inspected with the probe card. Typically, the probe card is positioned on an inspection machinery and the circuit board for inspection is pressed onto the probe needles by a fixture clamp. Therefore, each one of the probe needles is electrically connected to the circuit board for inspection and the circuitry on the circuit board being inspected can be tested to determine its proper functioning and connections.

Known probe needle structure mostly comprises a sleeve having two electrodes with a spring connected between the two electrodes. One of the electrodes is fixed onto the inspection machinery and is electrically connected thereto; whereas the other electrode is moveably arranged inside the sleeve and is provided to be electrically connected to the circuit board for inspection. When a wafer touches the probe needle, the spring is compressed and exerts a force onto the moveable electrode such that the electrode is ensured to be in contact with the circuit board and is electrically connected thereto. Alternatively, the probe needle may comprise one movable electrode only and the spring can be used for providing an electrical connection of the electrode with the inspection machinery.

The probe needle is a tiny component and is often with a complex structure, which poses difficulties to the manufacturing of the parts and the assembly thereof. As known probe needle uses a spring as a means for stabling a conductive contact, it often occurs that such known probe needle is in poor contacts and frequently fails to establish electrical connections with the circuit board for inspection and the inspection machinery during errors of the manufacturing process.

In view of the above, the inventor seeks to overcome the aforementioned drawbacks of known arts and provides an improvement after extensive research and development as one of the objectives of the present invention.

### SUMMARY OF THE INVENTION

An objective of the present invention is to provide a testing probe needle with a stabilized connection.

To achieve the aforementioned objective, the present invention provides a semiconductor testing probe needle provided in a testing apparatus and electrically connected to both the testing apparatus and a circuit board for inspection; wherein the testing apparatus comprises an inspection main board. The semiconductor testing probe needle of the present invention comprises a conductive shaft, a spring column and a conductive wire. The conductive shaft includes two ends of a connection end and an inspection end for contacting with the circuit board for inspection. The spring column includes one end electrically connected to the connection end of the conductive shaft and another end abutting the inspection main board. The conductive wire is arranged along the spring column and includes one end electrically connected to the conductive shaft and another end provided to be electrically connected to the inspection main board.

Preferably, according to the aforementioned semiconductor testing probe needle, the conductive wire is arranged at an inner side of said spring column.

Preferably, according to the aforementioned semiconductor testing probe needle, said two ends of said spring column are a free end and a fixed end; said free end is electrically connected to said connection end of said conductive shaft and said fixed end abuts said inspection main board.

Preferably, according to the aforementioned semiconductor testing probe needle, said fixed end of said spring column has an outer diameter smaller than an outer diameter of said free end.

Preferably, according to the aforementioned semiconductor testing probe needle, said fixed end of said spring column extends with a tapered form.

Preferably, according to the aforementioned semiconductor testing probe needle, said fixed end of said spring column is mounted onto said connection end of said conductive shaft.

Preferably, according to the aforementioned semiconductor testing probe needle, said inspection end comprises a conductive contact for contacting with said circuit board for inspection.

Preferably, according to the aforementioned semiconductor testing probe needle, said conductive wire is electrically connected to said connection end of said conductive shaft.

The semiconductor testing probe needle of the present invention utilizes a conductive wire to establish electrical connections with the conductive shaft and the inspection main board such that the overall structure is simplified and facilitated for manufacturing of the parts and assembly thereof, which too effectively overcomes the drawbacks of the known arts.

### BRIEF DESCRIPTION OF DRAWING

FIG. 1 is an exploded view of a first embodiment of the semiconductor testing probe needle of the present invention;

FIG. 2 is a perspective view of the first embodiment of the semiconductor testing probe needle of the present invention;

FIG. 3 is an illustration showing the configuration of the first embodiment of the semiconductor testing probe needle of the present invention;

FIG. 4 is an illustration showing the state of use of the first embodiment of the semiconductor testing probe needle of the present invention; and

FIG. 5 is an illustration showing a second embodiment of the semiconductor testing probe needle of the present invention.

### DETAILED DESCRIPTION OF THE INVENTION

Please refer to FIG. 1 and FIG. 2. As shown in the figures, a first embodiment of the present invention provides a semiconductor testing probe needle comprising a conductive shaft 100, a spring column 200 and a conductive wire 300.

The conductive shaft 100 is preferably made of a metal material. Two ends of the conductive shaft 100 are a connection end 110 and an inspection end 120. The connection end 110 is used for connecting with the spring column 200, and an end portion of the inspection end 120 comprises a conductive contact 121 for contacting with the circuit board for inspection 40. The conductive contact 121 can be either of a cut-out slot or an arched-surface protrusion shape but the present invention is not limited to such shapes. The conductive shaft 100 further comprises a blocking portion 130, and the blocking portion 130 is arranged between the connection end 110 and the inspection end 120 and extends outward from the mid-section of the side wall of the conductive shaft 100; preferably, it extends outward in a shape of a circumferential shape to form a rod. In this embodiment, the blocking portion 130 is arranged to be adjacent to the connection end 110 but the present invention is not limited to such arrangements only.

The spring column 200 is electrically connected between the conductive shaft 100 and the inspection main board 20. The spring column 200 is preferably formed by a metal wire circumferentially stacked along a circular path and includes two ends of a free end 210 and a fixed end 220. The fixed end 220 preferably has an outer diameter smaller than an outer diameter of the free end, and the fixed end 220 extends in a tapered form to be of a conical shape. The free end 210 is mounted onto the connection end 110 of the conductive shaft 100, and the free end 210 preferably abuts one side of the connection end 110 adjacent to the blocking portion 130 of the conductive shaft 100.

The conductive wire 300 is preferably made of a metal and is arranged to along the extension of the spring column 200. One end of the conductive wire 300 is arranged at an inner side of the free end 210 of the spring column 200 and protrudes outward from the spring column 200 to connect to the blocking portion of the conductive shaft 100 as well as electrically connected to the conductive shaft 100. Another end of the conductive wire 300 extends along the inner side of the column spring 200 to the fixed end 220 of the spring column 200.

Please refer to FIG. 3, the semiconductor testing probe needle of the present invention is installed onto a testing apparatus 10 for inspecting a circuit board for inspection 40 and the circuit board for inspection 40 comprises soldering points 41. The aforementioned testing apparatus 10 comprises an inspection main board 20 and a probe needle base 30 connected to the inspection main board 20. The inspection main board 20 includes an inspection circuitry (not shown in the figure) thereon; the probe needle base 30 comprises a plurality of needle holes 31 arranged in an array formed thereon. In addition, one opening end of each one of the needle holes 31 faces toward the inspection main board 20 and is arranged corresponding to the layout of the inspection circuitry. The semiconductor testing probe needle of the present invention is received in one of the needle holes 31. The inspection end 120 of the conductive shaft 100 is arranged to protrude outward from the needle hole 31. The blocking portion 130 of the conductive shaft 100 abuts an inner edge of the needle hole 31 away from one side of the connection end 110, and the fixed end 220 abuts the inspection main board 30 such that the semiconductor testing probe needle of the present invention is secured within the needle hole 31. Furthermore, one end of the conductive wire 300 at the fixed end 220 of the spring column 200 is soldered onto the inspection main board 20 such that the inspection main board 20 is electrically connected to the conductive shaft 100.

As shown in FIG. 4, when the testing apparatus 10 is used for inspecting the circuit board for inspection 40, the circuit board for inspection 40 moves toward the testing apparatus 10 such that the soldering point 41 on the circuit board for inspection 40 is in contact with the inspection end 120 of the conductive shaft 100. The soldering point 41 is preferably inserted into the conductive contact 121 of the inspection end 120 such that the inspection end 120 is ensured to be in contact with the soldering point 41 and is electrically connected thereto. As the circuit board for inspection 40 moves closer, the inspection end 120 is pressed onto the circuit board for inspection 40 such that the conductive shaft 100 is under compression that forces the inspection end 120 to retract into the needle hole 31. As the conductive shaft 100 retracts back, the blocking portion 130 is able to press onto the spring column 200 to compress the spring column 200. Therefore, the circuit board for inspection 40 is electrically connected to the inspection circuitry and such that the connectivity of the circuit board for inspection 40 can be inspected by the inspection circuitry.

FIG. 5 shows a second embodiment of a semiconductor testing probe needle of the present invention comprising a conductive shaft 100, a spring column 200 and a conductive wire 300, which is of a structure, in general, similar to the one of the first embodiment recited above and their similar features are therefore omitted. This embodiment differs from the aforementioned first embodiment in that preferably, one end of the conductive wire 300 is axially connected to the free end 210 of the spring column 200 whereas another end of the conductive wire 300 extends along an inner side of the spring column 200 to the fixed end 220.

The semiconductor testing probe needle of the present invention is of a simplified structure to facilitate the manufacturing of the parts and assembly thereof, which utilizes the conductive wire 300 electrically connected to the conductive shaft 100 and to the inspection main board 20 in order to achieve a greater connection stability than the one using a spring. In addition, since the resistance of the conductive wire 300 is much smaller than the one of the spring, it is able to greatly reduce the decays of transmitted signals during the inspection. As a result, the semiconductor testing probe needle of the present invention is of the merits of reduced chance of having poor electrical connections in comparison to known arts and of greater connection stability in light of overcoming the drawbacks of the known arts.

It can be understood that the preferred embodiments of the present invention are provided for illustrative purposes only, which shall not be used to limit the scope of the present invention. Any other modifications and variations in relation to the spirit of the present invention and capable of generating substantially equivalent outcomes shall all be considered to be within the scope of the present invention.

What is claimed is:

1. A semiconductor testing probe needle provided in a testing apparatus and electrically connected to said testing apparatus and to a circuit board for inspection; said testing apparatus comprising an inspection main board, and said semiconductor testing probe needle comprising:
a conductive shaft having two ends of a connection end and an inspection end for contacting with said circuit board for inspection;
a spring column having one end electrically connected to said connection end of said conductive shaft and another end abutting said inspection main board; and
a conductive wire arranged along said spring column and having one end electrically connected to said conductive shaft and another end provided to be electrically connected to said inspection main board.

2. The semiconductor testing probe needle according to claim 1, wherein said conductive wire is arranged at an inner side of said spring column.

3. The semiconductor testing probe needle according to claim 1, wherein said two ends of said spring column are a free end and a fixed end; said free end is electrically connected to said connection end of said conductive shaft and said fixed end abuts said inspection main board.

4. The semiconductor testing probe needle according to claim 3, wherein said fixed end of said spring column has an outer diameter smaller than an outer diameter of said free end.

5. The semiconductor testing probe needle according to claim 3, wherein said fixed end of said spring column extends in a tapered form.

6. The semiconductor testing probe needle according to claim 3, wherein said fixed end of said spring column is mounted onto said connection end of said conductive shaft.

7. The semiconductor testing probe needle according to claim 1, wherein said inspection end comprises a conductive contact for contacting with said circuit board for inspection.

8. The semiconductor testing probe needle according to claim 1, wherein said conductive wire is electrically connected to said connection end of said conductive shaft.
